(19) United States
(12) Patent Application Publication
(10) Pub. No.: US 2025/0234573 A1
(43) Pub. Date: Jul. 17, 2025

(54) SOURCE/DRAIN (S/D) EPITAXIAL GROWTH IN GATE-ALL-AROUND (GAA) NANOSHEET DEVICE

(71) Applicant: Applied Materials, Inc., Santa Clara, CA (US)

(72) Inventors: San-Kuei LIN, Cupertino, CA (US); Pradeep K. SUBRAHMANYAN, Santa Clara, CA (US)

(21) Appl. No.: 18/979,201

(22) Filed: Dec. 12, 2024

Related U.S. Application Data
(60) Provisional application No. 63/620,083, filed on Jan. 11, 2024.

(51) Int. Cl. H10D 30/01; H10D 30/00

(52) U.S. Cl. CPC H10D 30/0196; H10D 30/0191; H10D 30/502; H10D 30/507

(57) ABSTRACT

A method of forming a portion of a gate-all-around field-effect transistor (GAA FET) nanosheet structure includes performing a trim back recess process to form recesses in inner spacers of a fin-shaped column in a first direction from a sidewall of the fin-shaped column, wherein the fin-shaped column includes a stack of nanosheet channels and sacrificial layers having the inner spacers on both sides thereof in the first direction, performing an interface epitaxial growth process to grow interface source/drain (S/D) epi layers from exposed surfaces of the nanosheet channels of the fin-shaped column on the sidewalls of the fin-shaped column, performing an etch back process to etch back the interface S/D epi layer and form a continuous surface of the interface S/D epi layer, and performing a full epitaxial growth process to fully grow an S/D epi layer from the continuous surface of the interface S/D epi layer.

### CROSS-REFERENCE TO RELATED APPLICATIONS

This application claims priority to U.S. Provisional Application Ser. No. 63/620,083 filed Jan. 11, 2024, which is herein incorporated by reference in its entirety.

### BACKGROUND

### Field

Embodiments described herein generally relate to semiconductor device fabrication, and more particularly, to forming high quality source/drain (S/D) epitaxial layers in a horizontally stacked gate-all-around field-effect transistor (GAA FET) nanosheet structure.

### Description of the Related Art

In efforts of miniaturization and performance enhancement in semiconductor electronics, complementary metal-oxide semiconductor (CMOS) technology has introduced planer transistors with low costs, low power consumption, and high packing density. The development of multigate devices such as fin field-effect transistor (FET) and gate-all-around (GAA) FET further offsets planer transistors.

GAA FETs further provide design flexibility, low operational voltage, high drive currents, high computational speed, and excellent performance within a smaller footprint area. However, in a GAA nanosheet structure, an inner spacer introduced to improve parasitic capacitance between source/drain (S/D) epitaxial layers and metal gates causes a challenge in fabrication of the S/D epitaxial layers, as epitaxial growth of S/D epitaxial layers (e.g., SiGe or SiP) on surfaces of nanosheet channels (e.g., Si) is prevented by the inner spacer (e.g., Si₃N₄). As a result, the S/D epitaxial layers include defects or strains.

Therefore, there is a need for process integration solution that alleviates the epitaxial growth defects or strains induced by the inner spacer and improves the quality of epitaxial growth.

### SUMMARY

Embodiments of the present disclosure provide a method of forming a portion of a gate-all-around field-effect transistor (GAA FET) nanosheet structure. The method includes performing a trim back recess process to form recesses in inner spacers of a fin-shaped column in a first direction from a sidewall of the fin-shaped column, wherein the fin-shaped column includes a stack of nanosheet channels sacrificial layers having the inner spacers on both sides thereof in the first direction, performing an interface epitaxial growth process to grow interface source/drain (S/D) epi layers from exposed surfaces of the nanosheet channels of the fin-shaped column on the sidewalls of the fin-shaped column, performing an etch back process to etch back the interface S/D epi layer and form a continuous surface of the interface S/D epi layer, and performing a full epitaxial growth process to fully grow an S/D epi layer from the continuous surface of the interface S/D epi layer.

Embodiments of the present disclosure also provide a method of forming a portion of a gate-all-around field-effect transistor (GAA FET) nanosheet structure. The method includes performing a trim back recess process to form recesses in inner spacers of each fin-shaped column of a plurality of fin-shaped columns in a first direction from sidewalls of the each fin-shaped column, wherein the each fin-shaped column includes a stack of nanosheet channels and sacrificial layers having the inner spacers on both sides thereof in the first direction, performing an interface epitaxial growth process to grow interface source/drain (S/D) epi layers from exposed surfaces of the nanosheet channels of the each fin-shaped column on the sidewalls of the each fin-shaped column, performing an etch back process to etch back the interface S/D epi layer and form a continuous surface of the interface S/D epi layer on the each fin-shaped column, and performing a full epitaxial growth process to fully grow an S/D epi layer from the continuous surface of the interface S/D epi layer of the each fin-shaped column.

Embodiments of the present disclosure further provide a semiconductor structure forming a portion of a gate-all-around field-effect transistor (GAA FET) nanosheet structure. The semiconductor structure includes a plurality of fin-shaped columns, each fin-shaped column of the plurality of fin-shaped columns including a stack of nanosheet channels and sacrificial layers having inner spacers on both sides thereof in a first direction, wherein the inner spacers each include a recess from sidewalls of the each fin-shaped column in the first direction, a dummy gate interfacing with the each fin-shaped column, a first gate spacer covering the dummy gate, a second gate spacer covering the first gate spacer, an interface source/drain (S/D) epi layer filling the recesses of the inner spacers, and an S/D epi layer on the interface S/D epi layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a multi-chamber processing system, according to one or more embodiments of the present disclosure.

FIGS. 2A and 2B are schematic views of a portion of a semiconductor structure that may form a horizontally stacked gate-all-around field-effect transistor (GAA FET) nanosheet structure, according to one or more embodiments of the present structure.

FIG. 3 depicts a process flow diagram of a method of forming a semiconductor structure that may form a horizontally stacked gate-all-around field-effect transistor (GAA FET) nanosheet structure, according to one embodiment.

FIGS. 4A, 4A′, 4B, and 4C are schematic views of a portion of a semiconductor structure corresponding to various states of the method of FIG. 3.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide methods for forming high quality source/drain (S/D) epitaxial layers in a horizontally stacked gate-all-around field-effect transistor (GAA FET) nanosheet structure. The methods include forming recesses in inner spacers adjacent to nanosheet channels, growing a portion of S/D epitaxial layers from surfaces of the nanosheet channels to cover surfaces of the inner spacers, and fully growing the S/D epitaxial layers over the portion of the S/D epitaxial layers.

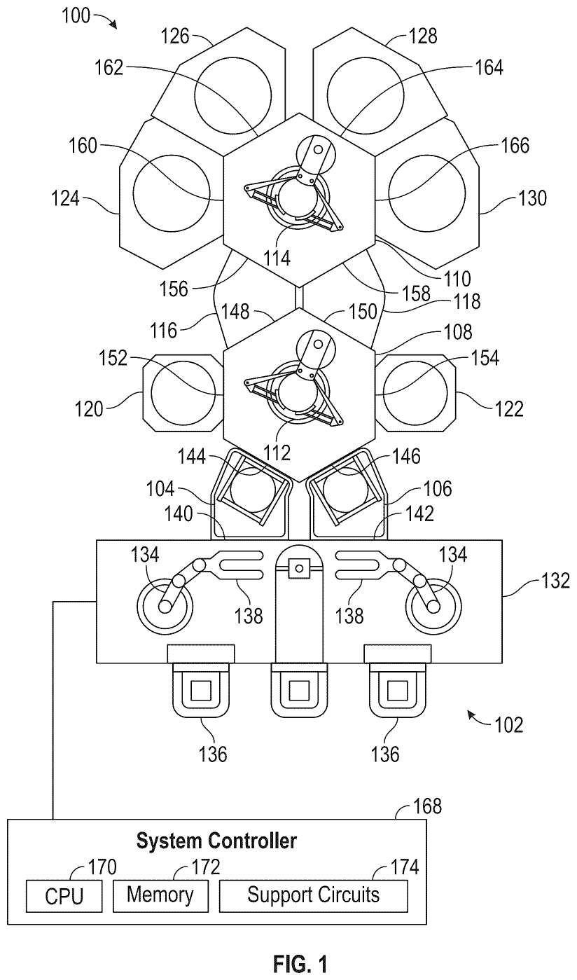

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing etch processes, the processing chamber 122 can be capable of performing cleaning processes, the processing chamber 124 can be capable of performing selective removal processes, the processing chamber 126 can be capable of performing chemical vapor deposition (CVD) deposition processes, and the processing chambers 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126 may be a W×Z™ chamber available from Applied Materials of Santa Clara, Calif. The processing chamber 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

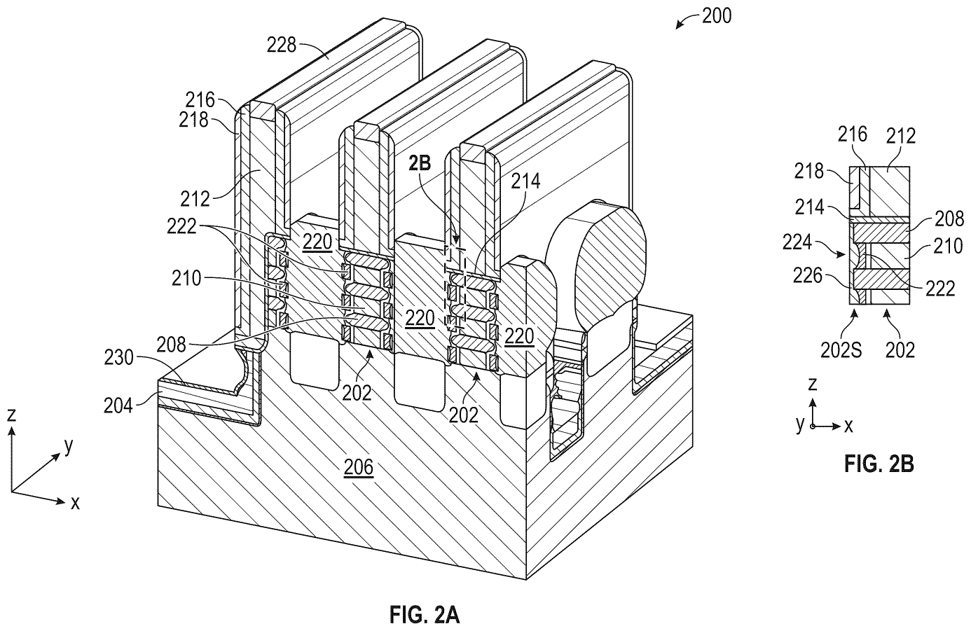

FIG. 2A is an isometric view of a portion of a semiconductor structure 200 that may form a horizontally stacked gate-all-around field-effect transistor (GAA FET) nanosheet structure, according to one or more embodiments of the present structure. FIG. 2B is a cross-sectional view of a portion of the semiconductor structure 200.

As shown in FIGS. 2A and 2B, the semiconductor structure 200 includes fin-shaped columns 202 extending in the Z direction that are isolated from adjacent fin-shaped columns 202 in the Y direction by a shallow trench isolation (STIs) 204 formed within a substrate 206. Each fin-shaped column 202 includes a stack of nanosheet channels 208 and sacrificial layers 210, and interfaces with a dummy gate 212 via a dummy oxide layer 214. The dummy gate 212 is covered by a first gate spacer 216 and a second gate spacer 218. The semiconductor structure 200 further include source/drain (S/D) epi layers 220 that are electrically isolated from the sacrificial layers 210 by inner spacers 222 disposed on both sides of the sacrificial layers 210 in the X direction.

The fin-shaped columns 202 may each have a width in the Y direction of between about 6 nm and about 200 nm. A pitch between adjacent dummy gates 212 in the X direction may be between about 40 nm and about 80 nm. As shown, the fin-shaped columns 202 each include three pairs of the nanosheet channels 208 and the sacrificial layers 210. However, in some embodiments, the fin-shaped columns 202 each include between 3 and 8 pairs of the nanosheet channels 208 and the sacrificial layers 210.

The nanosheet channels 208 may be formed of silicon (Si), germanium (Ge), silicon germanium (SiGe), or indium gallium zinc oxide (IGZO), each having a thickness of between about 3 nm and about 10 nm. The sacrificial layers 210 may be formed of silicon germanium (SiGe) with a ratio of germanium (Ge) ranging between 10% and 60%. In some other embodiments, the sacrificial layers 210 may be formed of silicon oxide (SiO₂). The sacrificial layers 210 may each have a thickness of between about 4 nm and about 10 nm.

The term “substrate” as used herein refers to a layer of material that serves as a basis for subsequent processing operations and includes a surface to be cleaned. The substrate 206 may be a silicon based material or any suitable insulating materials or conductive materials as needed. The substrate may include a material such as crystalline silicon (e.g., Si<100> or Si<111>), silicon oxide, strained silicon, silicon germanium, doped or undoped polycrystalline silicon, doped or undoped silicon wafers and patterned or non-patterned wafers, silicon on insulator (SOI), carbon doped silicon oxides, silicon nitride, doped silicon, germanium, gallium arsenide, glass, or sapphire.

The STIs 204 may be formed of silicon oxide (SiO₂). The dummy gates 212 may be formed of polycrystalline silicon (Si). The dummy oxide layer 214 may be formed of silicon oxide (SiO₂).

The first gate spacers 216 and the second gate spacers 218 may be formed of low-k dielectric material, such as silicon nitride (Si₃N₄), silicon oxycarbide (SiOC), silicon oxy-carbon-nitride (SiOCN), or silicon carbon nitride (SiCN).

The S/D epi layer 220 may be formed of epitaxially grown silicon germanium (SiGe) with a ratio of germanium (Ge) ranging between 25% and 50%, doped with p-type dopants such as boron (B) or gallium (Ga), with a concentration of between about 1×10¹⁸ cm⁻³ and 5×10²¹ cm⁻³, or epitaxially grown silicon (Si), doped with n-type dopants, such as phosphorus (P), arsenic (As), or antimony (Sb), with a concentration of between about 1×10¹⁸ cm⁻³ and 5 x·10²¹ cm⁻³.

The inner spacer 222 may be formed of dielectric material that has etch selectivity from the first gate spacer 216 and the second gate spacer 218, such as silicon nitride (Si₃N₄) silicon boron carbon nitride (SiBCN), silicon oxy-carbon-nitride (SiOCN), silicon oxycarbide (SiOC), organosilicate glass (SiCOH), or any combination thereof, having a thickness of between about 3 nm and about 8 nm. The inner spacers 222 each have a recess 224 from sidewalls 202S of the fin-shaped column 202 in the X direction. The recesses 224 may each have a depth in the X direction of between about 2 nm and about 3 nm. The recesses 224 are each filled with an interface S/D epi layer 226 that is merged with the S/D epi layer 220.

In FIG. 2A, a hard mask 228 used to pattern the dummy gates 212 and a hard mask 230 used to pattern STIs 204 during fabrication are shown. The hard mask 228 may be formed of silicon nitride (Si₃N₄) or silicon oxynitride (SiON). The hard mask 230 may be formed of silicon nitride (Si₃N₄), silicon oxynitride (SiON), or aluminum oxide (Al₂O₃).

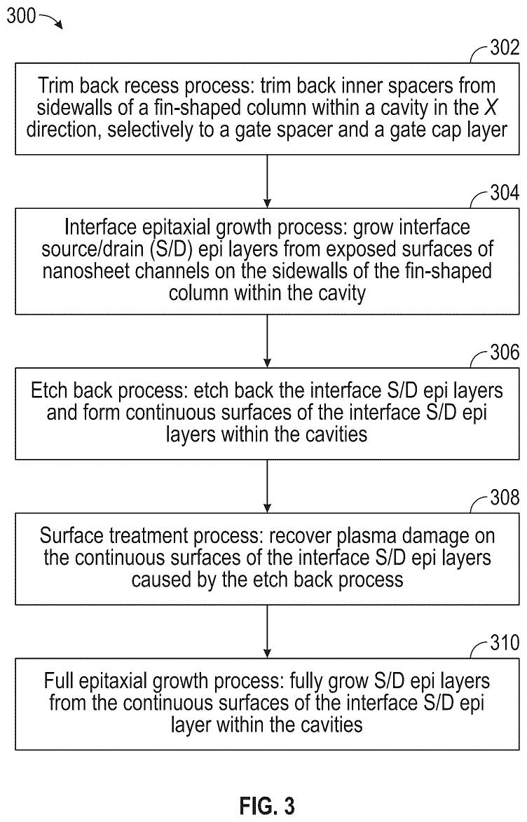

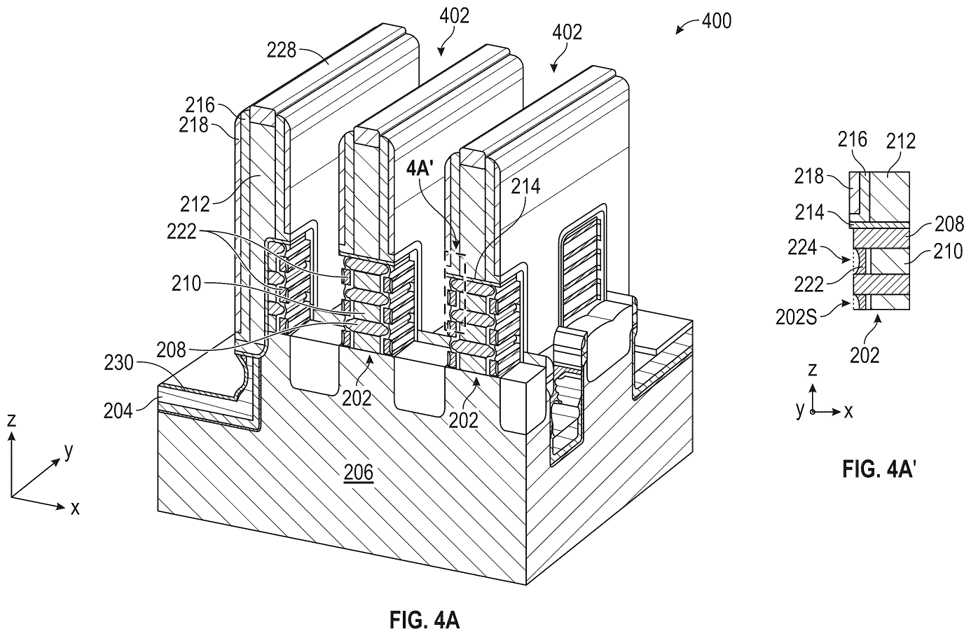

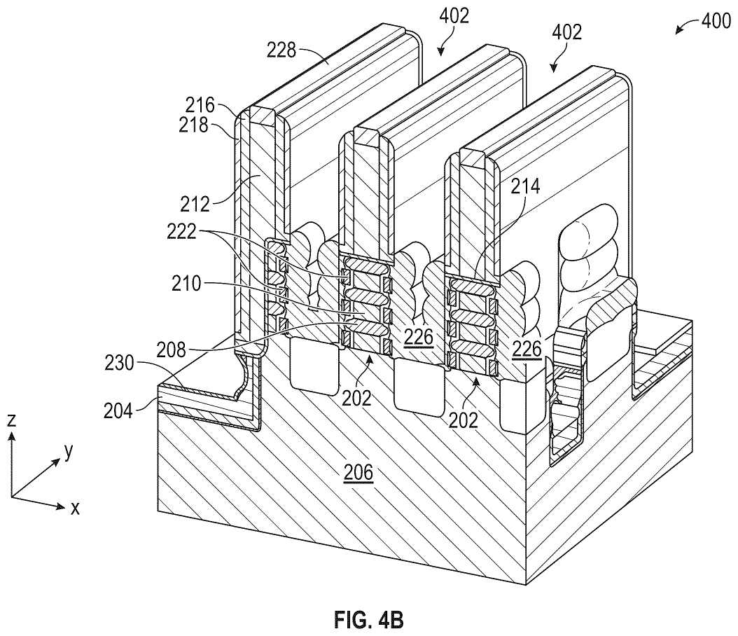

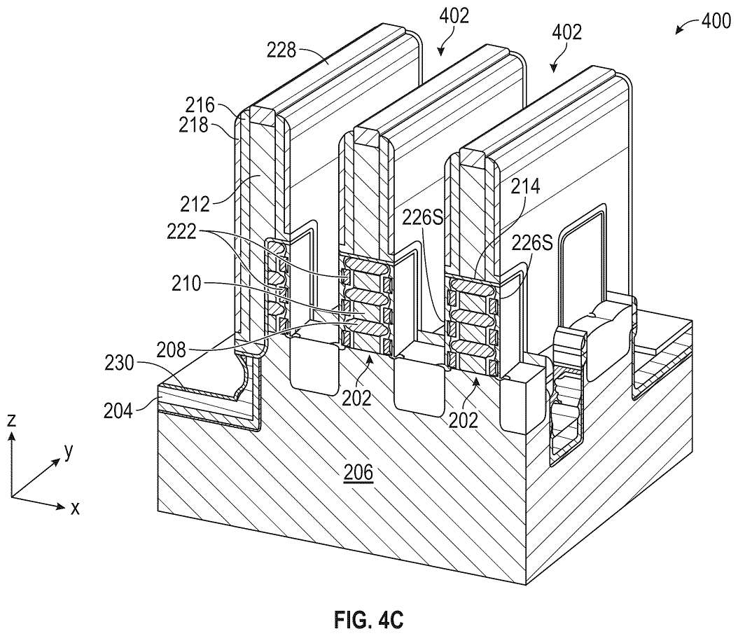

FIG. 3 depicts a process flow diagram of a method 300 of forming a semiconductor structure 400 that may be the semiconductor structure 200 forming a portion of a horizontally stacked gate-all-around field-effect transistor (GAA FET) nanosheet structure, according to one or more embodiments of the present disclosure. FIGS. 4A, 4B, and 4C are isometric views of a portion of the semiconductor structure 400 corresponding to various states of the method 300. FIG. 4A′ is a cross-sectional view of a portion of the semiconductor structure 400. It should be understood that FIGS. 4A, 4A′, 4B, and 4C illustrate only partial schematic views of the semiconductor structure 400, and the semiconductor structure 400 may contain any number of transistor sections and additional materials having aspects as illustrated in the figures. It should also be noted that although the method illustrated in FIG. 3 is described sequentially, other process sequences that include one or more operations that have been omitted and/or added, and/or has been rearranged in another desirable order, fall within the scope of the embodiments of the disclosure provided herein.

The semiconductor structure 400 shown in FIG. 4A may be formed by epitaxially growing a stack of alternating nanosheets of silicon (Si) and sacrificial layers of silicon germanium (SiGe) on a substrate 206, patterning the stack to defining fin-shaped columns 202 extending in the Z direction and forming cavities 402, and forming STIs 204 to isolate neighboring fin-shaped columns 202 within the substrate 206 using a hard mask 230. The nanosheets of silicon (Si) in the fin-shaped columns 202 are nanosheet channels 208, and the sacrificial layers of silicon germanium (SiGe) in the fin-shaped columns 202 are sacrificial layers 210 to be replaced with replacement metal gate (RMG) stacks. The sacrificial layers 210 have inner spacers 222 on both sides of the sacrificial layers 210 in the X direction. Dummy gates 212 are formed and patterned to reveal the cavities 402 using a hard mask 228, and interface with the fin-shaped columns 202 via a dummy oxide layer 214. A first gate spacer 216 and a second gate spacer 218 are formed over the dummy gate 212. Inner spacers 222 are formed to isolate the sacrificial layers 210 from source/drain (S/D) epi layers 220 to be formed.

The fin-shaped columns 202 may each have a width in the Y direction of between about 6 nm and about 200 nm. A pitch between adjacent dummy gates 212 in the X direction may be between about 40 nm and about 80 nm. As shown, the fin-shaped columns 202 each include three pairs of the nanosheet channels 208 and the sacrificial layers 210. However, in some embodiments, the fin-shaped columns 202 each include between 3 and 8 pairs of the nanosheet channels 208 and the sacrificial layers 210.

The nanosheet channels 208 may be formed of silicon (Si), germanium (Ge), silicon germanium (SiGe), or indium gallium zinc oxide (IGZO), each having a thickness of between about 3 nm and about 10 nm. The sacrificial layers 210 may be formed of silicon germanium (SiGe) with a ratio of germanium (Ge) ranging between 10% and 60%. In some other embodiments, the sacrificial layers 210 may be formed of silicon oxide (SiO₂). The sacrificial layers 210 may each have a thickness of between about 4 nm and about 10 nm.

The STIs 204 may be formed of silicon oxide (SiO₂). The dummy gates 212 may be formed of polycrystalline silicon (Si). The dummy oxide layer 214 may be formed of silicon oxide (SiO₂).

The first gate spacers 216 and the second gate spacers 218 may be formed of low-k dielectric material, such as silicon nitride (Si₃N₄), silicon oxycarbide (SiOC), silicon oxy-carbon-nitride (SiOCN), or silicon carbon nitride (SiCN).

The inner spacer 222 may be formed of silicon nitride (Si₃N₄) silicon boron carbon nitride (SiBCN), silicon oxy-carbon-nitride (SiOCN), silicon oxycarbide (SiOC), organosilicate glass (SiCOH), or any combination thereof, having a thickness of between about 3 nm and about 8 nm.

The hard masks 228 and 230 may be formed of silicon nitride (Si₃N₄) or silicon oxynitride (SiON).

The method 300 begins with block 302, in which a trim back recess process is performed to trim back the inner spacers 222 from sidewalls 202S of the fin-shaped column 202 within the cavity 402 in the X direction, selectively to the first gate spacer 216 and the second gate spacer 218, as shown in FIGS. 4A and 4A′. The trim back recess process may include any appropriate isotropic radical etch process, such as a selective removal plasma (SRP) process, or wet etch process, performed in a Selectra™ Etch chamber available from Applied Materials of Santa Clara, Calif., or the processing chamber 120 shown in FIG. 1.

The trim back recess process forms recesses 224 in the inner spacers 222 underneath the first gate spacer 216 and the second gate spacer 218 within the cavity 402. The recesses 224 may each have a depth in the X direction of between about 2 nm and about 3 nm.

In some embodiments, the trim back recess process also trims back the nanosheet channels 208 from the cavity 402, separately from or simultaneously with the trim back of the inner spacers 222.

In block 304, an interface epitaxial growth process is performed to grow interface source/drain (S/D) epi layers 226 from exposed surfaces of the nanosheet channels 208 on the sidewalls 202S of the fin-shaped column 202 within the cavity 402, as shown in FIG. 4B. In some embodiments, the interface S/D epi layers 226 are partially grown within the cavity 402. In some embodiments, the interface S/D epi layers 226 are fully grown within the cavity 402. The interface epitaxial growth process may be a selective epitaxial deposition process, performed in a processing chamber, such as the processing chamber 126, 128, or 130 shown in FIG. 1.

The interface S/D epi layers 226 are grown selectively from the nanosheet channels 208 and fill the recesses 224 in the inner spacers 222. The interface S/D epi layers 226 are grown at least to fully cover the surfaces of the inner spacers 222 within the cavity 402.

The interface S/D epi layer 226 may be formed of silicon germanium (SiGe) with a ratio of germanium (Ge) ranging between 25% and 50%, doped with p-type dopants such as boron (B) or gallium (Ga), with a concentration of between about 1×10¹⁸ cm⁻³ and 5 x·10²¹ cm⁻³, or silicon (Si), doped with n-type dopants, such as phosphorus (P), arsenic (As), or antimony (Sb), with a concentration of between about 1×10¹⁸ cm⁻³ and 5 x·10²¹ cm⁻³.

The selective epitaxial deposition process may include a conformal epitaxial deposition process and an etch process. In the epitaxial deposition process in which the semiconductor structure 400 is exposed to a deposition gas, an amorphous layer of silicon (Si) may be formed on surfaces of the inner spacers 222, the first gate spacer 216, the second gate spacer 218, and the STIs 204 (e.g., silicon dioxide (SiO₂)), while an epitaxial layer of silicon (Si) may be formed on exposed surfaces of the nanosheet channels 208 and the substrate 206 (e.g., silicon (Si)) within the cavities 402. In the subsequent etch process, the amorphous layer can be etched at a faster rate than the epitaxial layer, by an appropriate etching gas. Thus, an overall result of the epitaxial deposition process and the etch process combined can be a selective epitaxial growth on the surfaces of the nanosheet channels 208 and the substrate 206 within the cavities 402, while minimizing growth, if any, on the surfaces of the inner spacers 222, the first gate spacer 216, the second gate spacer 218, and the STIs 204.

In some embodiments, the deposition gas includes a silicon-containing precursor, a germanium containing precursor, and a dopant source. The silicon-containing precursor may include silane (SiH₄), disilane (Si₂H₆), tetrasilane (Si₄H₁₀), or a combination thereof. The etching gas includes an etchant gas and a carrier gas. The etchant gas may include halogen-containing gas, such as hydrogen chloride (HCl), chlorine (Cl₂), or hydrogen fluoride (HF). The carrier gas may include nitrogen (N₂), argon (Ar), helium (He), or hydrogen (H₂).

The selective deposition may be performed at a low temperature less than about 450° C. and at a pressure of between about 5 Torr and about 600 Torr, or at a high temperature at about 700° C. and a pressure of below about 600 Torr.

A cycle of the epitaxial deposition and etch processes may be repeated as needed to obtain a desired thickness of the interface S/D epi layer 226.

In block 306, an etch back process is performed to etch back the interface S/D epi layers 226 grown in the selective deposition process in 304 and form continuous surfaces 226S of the interface S/D epi layers 226 within the cavities 402, as shown in FIG. 4C.

The etch back process may include an anisotropic etch process, such as a reactive ion etching (RIE) process, using a plasma formed from a gas including hydrogen (H), argon (Ar), helium (He), or a combination thereof, formed in a processing chamber, such as CENTRIS® SYM3™ etch chamber available from Applied Materials, Inc. of Santa Clara, California, or the processing chamber 120 shown in FIG. 1.

In block 308, a surface treatment process is performed to recover plasma damage on the continuous surfaces 226S of the interface S/D epi layers 226 caused by the etch back process in block 306 and prepare surfaces for the full epitaxial growth process in block 310.

The surface treatment process may include a thermal treatment process (e.g., hydrogen (H₂) bake), a rapid thermal process (RTP), or a plasma treatment process, performed in a pre-clean chamber, such as the processing chamber 122 shown in FIG. 1. In the plasma treatment process, the continuous surfaces 226S of the interface S/D epi layers 226 are exposed to a plasma formed from a process gas including hydrogen (H₂), a mixture of hydrogen (H₂) and nitrogen (N₂), a mixture of hydrogen (H₂) and methane (CH₄), a mixture of hydrogen (H₂) and noble gas (e.g., helium (He), argon (Ar)), or any combination thereof.

In block 310, a full epitaxial growth process is performed to fully grow S/D epi layers 220 from the continuous surfaces 226S of the interface S/D epi layer 226 within the cavities 402 to arrive the semiconductor structure 200 shown in FIGS. 2A and 2B.

The S/D epi layers 220 may be formed of the same materials as the interface S/D epi layer 226. The full epitaxial growth process may be the same as or similar to the selective epitaxial deposition process in block 304.

Since the S/D epi layers 220, according to the embodiments described herein, are grown from the continuous surfaces 226S of the interface S/D epi layers 226, instead of on exposed surfaces of the inner spacers 222, the S/D epi layers 220 are of high quality with reduced defects or strains, increased size uniformity, and increased shape controllability.

The embodiments described herein provide methods for forming high quality source/drain (S/D) epitaxial layers in a horizontally stacked gate-all-around field-effect transistor (GAA FET) nanosheet structure. The methods include forming recesses in inner spacers adjacent to nanosheet channels, growing a portion of S/D epitaxial layers from surfaces of the nanosheet channels to cover surfaces of the inner spacers, and fully growing the S/D epitaxial layers over the portion of the S/D epitaxial layers.

While the foregoing is directed to embodiments of the present disclosure, other and further embodiments of the disclosure may be devised without departing from the basic scope thereof, and the scope thereof is determined by the claims that follow.

1. A method of forming a portion of a gate-all-around field-effect transistor (GAA FET) nanosheet structure, comprising:
performing a trim back recess process to form recesses in inner spacers of a fin-shaped column in a first direction from a sidewall of the fin-shaped column,
wherein the fin-shaped column comprises a stack of nanosheet channels and sacrificial layers having the inner spacers on both sides thereof in the first direction;
performing an interface epitaxial growth process to grow interface source/drain (S/D) epi layers from exposed surfaces of the nanosheet channels of the fin-shaped column on the sidewalls of the fin-shaped column;
performing an etch back process to etch back the interface S/D epi layer and form a continuous surface of the interface S/D epi layer; and
performing a full epitaxial growth process to fully grow an S/D epi layer from the continuous surface of the interface S/D epi layer.

2. The method of claim 1, further comprising:
prior to the full epitaxial growth process, performing a surface treatment process to recover damage on the continuous surface of the interface S/D epi layer.

3. The method of claim 1, wherein:
the nanosheet channels comprises silicon (Si), each having a thickness of between 3 nm and 10 nm, and
the sacrificial layers comprise silicon germanium (SiGe) with a ratio of germanium (Ge) ranging between 10% and 60%, each having a thickness of between 4 nm and 10 nm.

4. The method of claim 1, where the inner spacers comprise silicon nitride (Si₃N₄) silicon boron carbon nitride (SiBCN), silicon oxy-carbon-nitride (SiOCN), silicon oxycarbide (SiOC), organosilicate glass (SiCOH), or any combination thereof, each having a thickness of between 3 nm and 8 nm.

5. The method of claim 1, wherein the trim back recess process comprises a selective removal plasma (SRP) process to etch the inner spacers of the fin-shaped column selectively to a first gate spacer and a second gate spacer covering a dummy gate that interfaces with the fin-shaped column.

6. The method of claim 5, wherein the first gate spacer and the second gate spacer comprise nitride (Si₃N₄), silicon oxycarbide (SiOC), silicon oxy-carbon-nitride (SiOCN), or silicon carbon nitride (SiCN).

7. The method of claim 1, wherein the etch back process comprises a reactive ion etching (RIE) process.

8. The method of claim 1, wherein:
the interface S/D epi layer and the S/D epi layer comprise epitaxially grown silicon germanium (SiGe) doped with p-type dopants, or epitaxially grown silicon (Si), doped with n-type dopants.

9. A method of forming a portion of a gate-all-around field-effect transistor (GAA FET) nanosheet structure, comprising:
performing a trim back recess process to form recesses in inner spacers of each fin-shaped column of a plurality of fin-shaped columns in a first direction from sidewalls of the each fin-shaped column,
wherein the each fin-shaped column comprises a stack of nanosheet channels and sacrificial layers having the inner spacers on both sides thereof in the first direction;
performing an interface epitaxial growth process to grow interface source/drain (S/D) epi layers from exposed surfaces of the nanosheet channels of the each fin-shaped column on the sidewalls of the each fin-shaped column;
performing an etch back process to etch back the interface S/D epi layer and form a continuous surface of the interface S/D epi layer on the each fin-shaped column; and
performing a full epitaxial growth process to fully grow an S/D epi layer from the continuous surface of the interface S/D epi layer of the each fin-shaped column.

10. The method of claim 9, further comprising:
prior to the full epitaxial growth process, performing a surface treatment process to recover damage on the continuous surface of the interface S/D epi layer on the each fin-shaped column.

11. The method of claim 9, wherein:
the nanosheet channels comprises silicon (Si), each having a thickness of between 3 nm and 10 nm, and
the sacrificial layers comprise silicon germanium (SiGe) with a ratio of germanium (Ge) ranging between 10% and 60%, each having a thickness of between 4 nm and 10 nm.

12. The method of claim 9, where the inner spacers comprise silicon nitride (Si₃N₄) silicon boron carbon nitride (SiBCN), silicon oxy-carbon-nitride (SiOCN), silicon oxycarbide (SiOC), organosilicate glass (SiCOH), or any combination thereof, each having a thickness of between 3 nm and 8 nm.

13. The method of claim 9, wherein the trim back recess process comprises a selective removal plasma (SRP) process to etch the inner spacers of the each fin-shaped column selectively to a first gate spacer and a second gate spacer covering a dummy gate that interfaces with the each fin-shaped column.

14. The method of claim 13, wherein the first gate spacer and the second gate spacer comprise nitride (Si₃N₄), silicon oxycarbide (SiOC), silicon oxy-carbon-nitride (SiOCN), or silicon carbon nitride (SiCN).

15. The method of claim 9, wherein the etch back process comprises a reactive ion etching (RIE) process.

16. The method of claim 9, wherein:
the interface S/D epi layers and the S/D epi layers comprise epitaxially grown silicon germanium (SiGe) doped with p-type dopants, or epitaxially grown silicon (Si), doped with n-type dopants.

17. A semiconductor structure forming a portion of a gate-all-around field-effect transistor (GAA FET) nanosheet structure, comprising:
a plurality of fin-shaped columns, each fin-shaped column of the plurality of fin-shaped columns comprising a stack of nanosheet channels and sacrificial layers having inner spacers on both sides thereof in a first direction, wherein the inner spacers each include a recess from sidewalls of the each fin-shaped column in the first direction;
a dummy gate interfacing with the each fin-shaped column;
a first gate spacer covering the dummy gate;
a second gate spacer covering the first gate spacer;
an interface source/drain (S/D) epi layer filling the recesses of the inner spacers; and
an S/D epi layer on the interface S/D epi layer.

18. The semiconductor structure of claim 17, wherein:
a pitch between the dummy gates interfacing adjacent fin-shaped columns of the plurality of fin-shaped columns in the first direction is between 40 nm and 80 nm,
the nanosheet channels comprises silicon (Si), each having a thickness of between 3 nm and 10 nm, and
the sacrificial layers comprises silicon germanium (SiGe) with a ratio of germanium (Ge) ranging between 10% and 60%, each having a thickness of between 4 nm and 10 nm.

19. The semiconductor structure of claim 17, where the inner spacers comprise silicon nitride (Si₃N₄) silicon boron carbon nitride (SiBCN), silicon oxy-carbon-nitride (SiOCN), silicon oxycarbide (SiOC), organosilicate glass (SiCOH), or any combination thereof, each having a thickness of between 3 nm and 8 nm.

20. The semiconductor structure of claim 17, wherein the first gate spacer and the second gate spacer comprise nitride (Si₃N₄), silicon oxycarbide (SiOC), silicon oxy-carbon-nitride (SiOCN), or silicon carbon nitride (SiCN).
